(19) United States
(12) Patent Application Publication
(10) Pub. No.: US 2019/0123246 A1
(43) Pub. Date: Apr. 25, 2019

(54) LIGHTING SYSTEMS AND METHODS COMBINING VISIBLE AND NON-VISIBLE LIGHT CONVERTING PHOSPHOR

(71) Applicant: DOMINANT Opto Technologies Sdn Bhd, Melaka (MY)

(72) Inventors: Tek Beng Low, Melaka (MY); Eng Wah Tan, Melaka (MY); Chee Sheng Lim, Melaka (MY)

(73) Assignee: DOMINANT Opto Technologies Sdn Bhd, Melaka (MY)

(21) Appl. No.: 15/797,843

(22) Filed: Oct. 30, 2017

(30) Foreign Application Priority Data
Oct. 25, 2017 (MY) PI2017704026

(51) Int. Cl. H01L 33/50

(52) U.S. Cl. CPC H01L 33/504; H01L 2933/0041; H01L 33/505; H01L 33/507; H01L 33/508

(57) ABSTRACT

A lighting system combining visible and non-visible light converting phosphor, includes, a light emitting diode (LED) package, a light emitting diode (LED) chip mounted on the light emitting diode (LED) package, a phosphor material covering the light emitting diode (LED) chip. In use, the phosphor material includes a first converting material and a second converting material. In addition, the spectral appearance of the lighting system is dependent upon a combination of the first converting material and the second converting material.

### BACKGROUND OF THE INVENTION

### Field of the Invention

Embodiments of the present invention relates to lighting systems, and more particularly, to lighting systems and methods of combining visible and non-visible light converting phosphor.

### Description of the Related Art

Generally, light emitting diodes (LEDs), are well known for a broad range of industrial applications, primarily due multiple advantages of LEDs, including, but not limited to, energy efficiency, low power consumption, small size, durability, long life, cost-effective manufacturing, low heat generation, and the like.

During manufacturing and production of LEDs, LED manufacturers focus majority of efforts on the testing and quality control of LEDs. Consequently, it is common to sort the LEDs as per different criteria, such as, for example, color (wavelength), lumen output (brightness or intensity), forward voltage, and the like. This process of sorting the LEDs is generally known as binning and the criteria of binning is commonly known as binning parameters.

A main goal of LED manufacturers is to make the binning process more efficient and in most applications, multiple LEDs are used and placed side by side, for example, in a display panel. Accordingly, to ensure uniformity in the display panel, it is important that the LEDs from the same bins are utilized because LEDs from different bins will have different light output, thereby resulting in non-uniform appearance when place side by side.

One of the challenges for LED manufacturers today is not to produce too many bins. However, this is unavoidable due to the variation in producing the LED chips and hence, it is not possible to produce perfectly similar chips without any variation in high volume.

Moreover, phosphor is used today as a converting material to produce white light in white LEDs. A typical white LED generally consists of blue chip (which produces blue light) and phosphor, whereby the blue light from the blue LED converts the phosphor material into yellow light, whereby when combined produces the white light.

Accordingly, there exists a need in the art for lighting systems and methods of combining visible and non-visible light converting phosphor, to reduce the number of bins required and to add more efficiency to the LED manufacturing process.

### SUMMARY OF THE INVENTION

Embodiments of the present disclosure disclose a lighting system combining visible and non-visible light converting phosphor, including, a light emitting diode (LED) package, a light emitting diode (LED) chip mounted on the light emitting diode (LED) package, and phosphor material covering the light emitting diode (LED) chip. In use, the phosphor material includes a first converting material and a second converting material.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a block diagram of a lighting system combining visible and non-visible light converting phosphor, in accordance with an embodiment of the present invention;

FIG. 2 illustrates a flow diagram of a method for manufacturing the lighting system combining visible and non-visible light converting phosphor, in accordance with an embodiment of the present invention;

FIG. 3 illustrates a block diagram of the lighting system combining visible and non-visible light converting phosphor, in accordance with multiple embodiments of the present invention; and,

FIG. 3 illustrates a block diagram of the lighting system combining visible and non-visible light converting phosphor, in accordance with multiple embodiments of the present invention; and,

FIG. 4 illustrates a spectrum of light output consisting of both visible and non-visible range, in accordance with multiple embodiments of the present invention.

While the present systems and methods have been described herein by way of example for several embodiments and illustrative drawings, those skilled in the art will recognize that the multiple embodiments disclosed hereinbelow are not limited to the embodiments or drawings described. It should be understood, that the drawings and detailed description thereto are not intended to limit embodiments to the particular form disclosed. Rather, the intention is to cover all modifications, equivalents and alternatives falling within the spirit and scope of the invention as defined by the appended claims. Any headings used herein are for organizational purposes only and are not meant to limit the scope of the description or the claims. As used herein, the word “can” and “may” is used in a permissive sense (i.e., meaning having the potential to), rather than the mandatory sense (i.e., meaning must). Similarly, the words “include”, “including”, and “includes” mean including, but not limited to.

### DETAILED DESCRIPTION

Various embodiments of the present invention relate to lighting systems and methods combining visible and non-visible light converting phosphor, aimed at limiting the number of bins by combining visible light converting phosphor (the type of phosphor which converts visible light from one wave length or light output to another visible light of different another wavelength or light output) with non-visible light converting phosphor (the type of phosphor which converts visible light to non-visible wavelengths like infrared or ultraviolet). Consequently, some of the visible light is converted to non-visible light range.

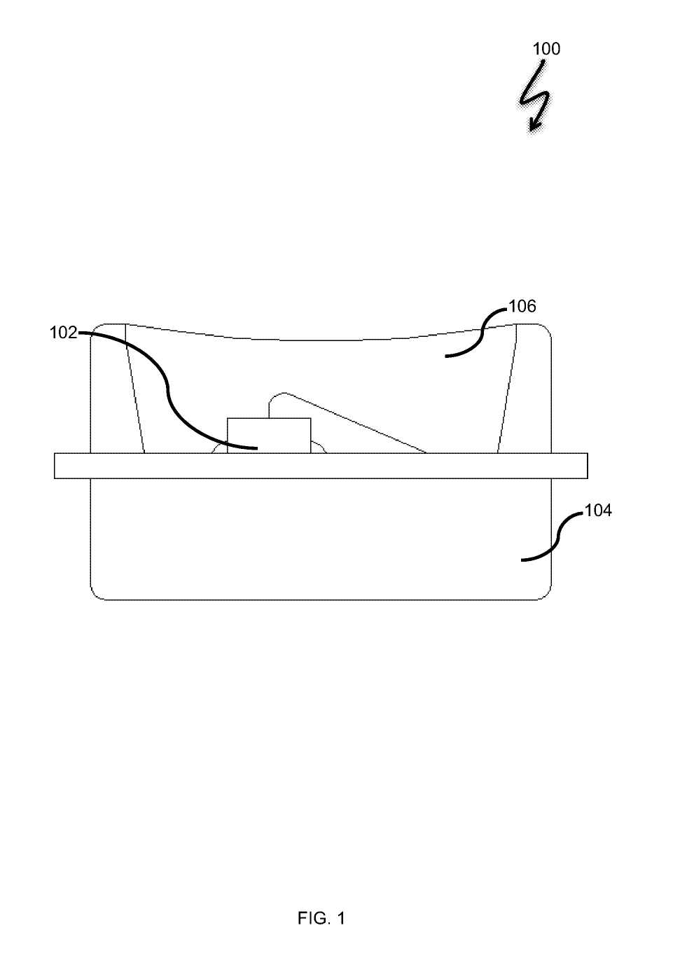

FIG. 1 illustrates a block diagram of a lighting system 100 combining visible and non-visible light converting phosphor. In accordance with an embodiment of the present invention, the lighting system 100 combining visible and non-visible light converting phosphor includes, a light emitting diode (LED) package 104, a light emitting diode (LED) chip 102 mounted on the light emitting diode (LED) package 104, a phosphor material 106 covering the light emitting diode (LED) chip 102. In use, the phosphor material 106 includes a first converting material and a second converting material. In addition, the spectral appearance of the lighting system 100 is dependent upon a combination of the first converting material and the second converting material.

In accordance with an embodiment of the present invention, the first converting material is phosphor which emits in the visible light spectrum and the second converting material is phosphor material that emits in the non-visible spectrum of light. Those of ordinary skills in the art will appreciate that the phosphor material can contain one or more than one phosphor types, as desired in a specific end use application of the invention. As used herein, “phosphor” refers to any material that converts the wavelengths of light irradiating it and/or that is fluorescent and/or phosphorescent and the specific components and/or formulation of the phosphor are not limitations of the present invention.

In accordance with an embodiment of the present invention, the light emitting diode (LED) chip 102 is a blue and/or a UV LED chip. In use, the light emitting diode (LED) chips 102 belong to one or more LED bins. Generally, the LED bins have a corresponding light output performance with respect to a light wavelength and/or light brightness, and/or other similar parameters. Those of ordinary skills in the art will appreciate that the combination of the first converting material and the second converting material provides one or more characteristics to the system 100. In use, such characteristics are dependent upon the first converting material that converts light in visible spectrum, and the second converting material that converts light in non-visible spectrum, as explained hereinabove.

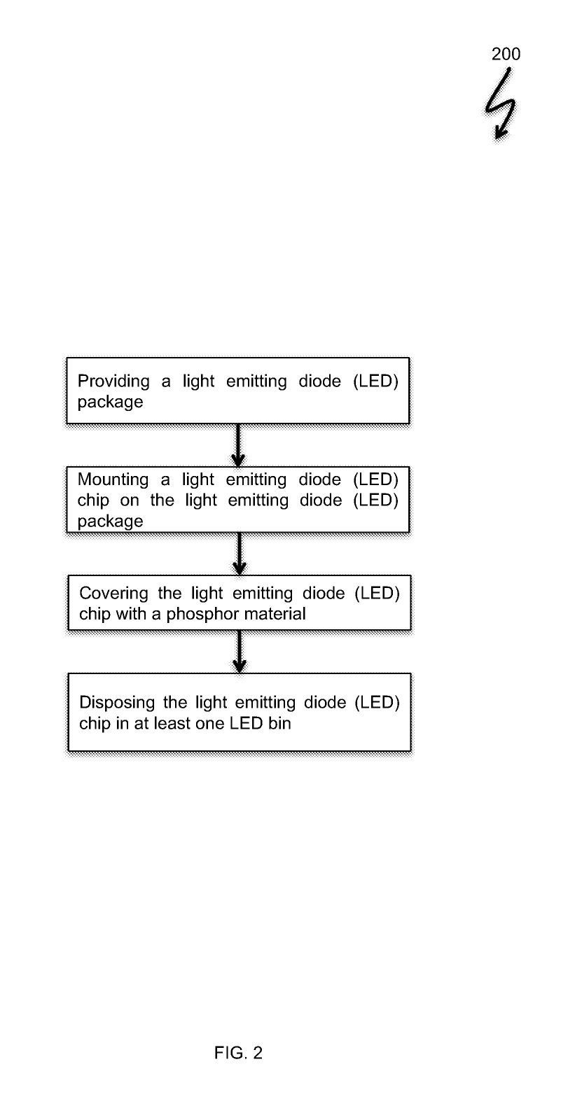

FIG. 2 illustrates a flow diagram of a method 200 for manufacturing the lighting system combining visible and non-visible light converting phosphor. In accordance with an embodiment of the present invention, the method 200 of manufacturing a lighting system combining visible and non-visible light converting phosphor, includes the steps of, providing a light emitting diode (LED) package; mounting at least one light emitting diode (LED) chip on the light emitting diode (LED) package; and, covering the at least one light emitting diode (LED) chip with a phosphor material. In use, the phosphor material includes a first converting material and a second converting material, and the spectral appearance of the lighting system is dependent upon a combination of the first converting material and the second converting material.

In accordance with an embodiment of the present invention, the method 200 further includes disposing the light emitting diode (LED) chip in at least one LED bin, as discussed above.

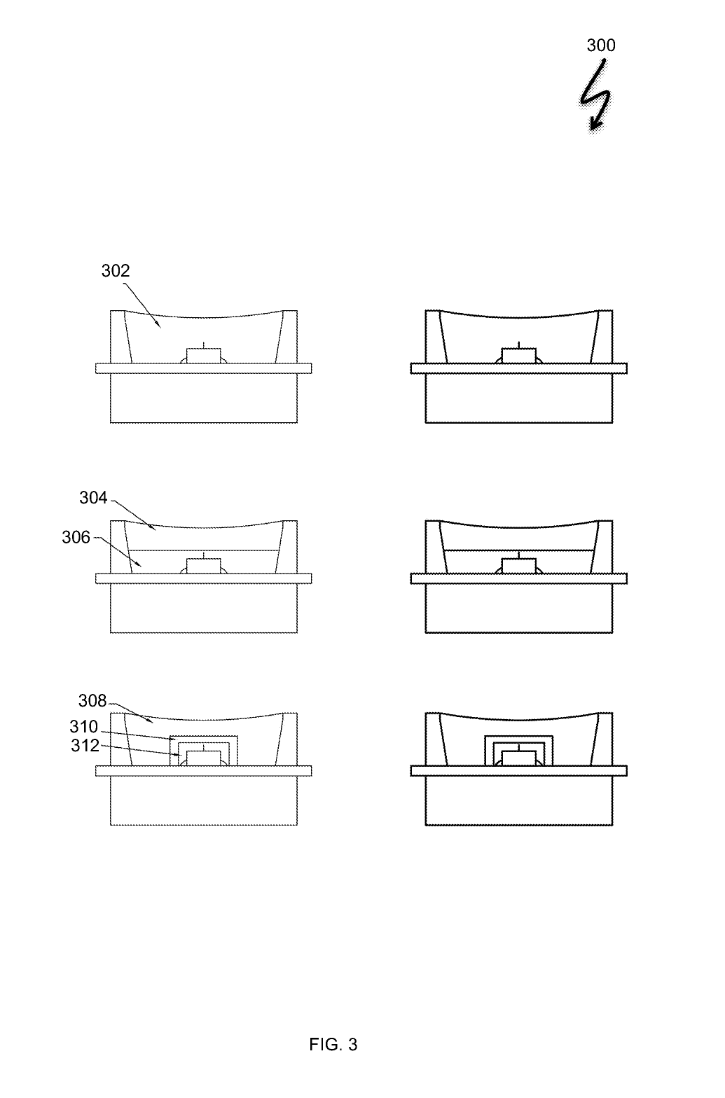

FIG. 3 illustrates a block diagram of the lighting system 300 combining visible and non-visible light converting phosphor, in accordance with multiple embodiments of the present invention. As seen therein, material 302 refers to a combination of non visible light converting phosphor material and visible light converting phosphor material. Additionally, material 304 refers to visible light converting phosphor material and material 306 refers to non visible light converting phosphor material. Also, material 308 refers to clear material, 310 refers to visible light converting phosphor material and 312 refers to non visible light converting phosphor material. Consequently, as may be seen, different types of materials may be employed for multiple embodiments as disclosed herein.

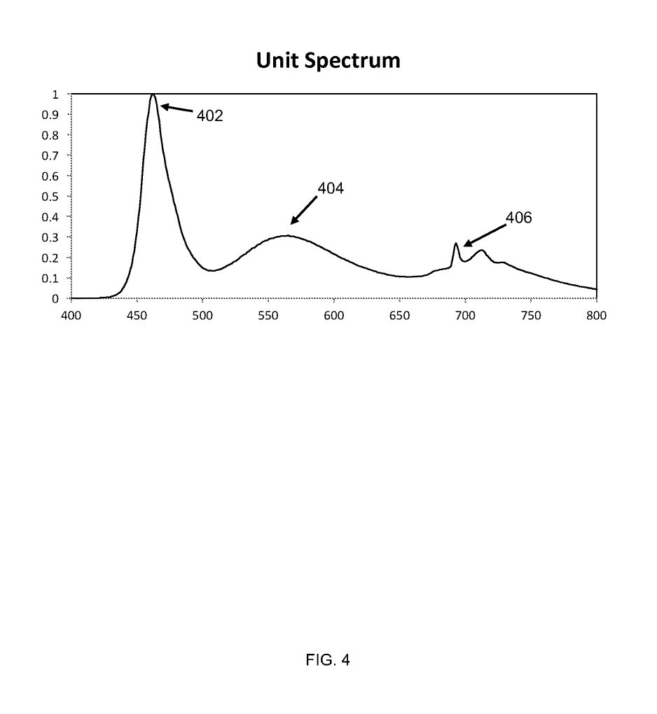

Those of ordinary skills in the art will appreciate that the first converting material includes a generic material that absorbs light of a shorter wavelength from the LED chip and converts it into polychromatic light with longer wavelengths in the visible wavelength range. In use, the typical visible range output is from 480 nm to 650 nm. In addition, the second material absorbs light of a shorter wavelength from the LED chip and converts it into light with longer wavelength in the non-visible wavelength range or greater than 680 nm. FIG. 4 illustrates a spectrum of the light output consisting of both the visible and non-visible range. As illustrated therein, 402 represents LED, 404 represents visible light converting phosphor material and 406 represents non visible light converting phosphor material.

Subsequently, the first converting material allows the flexibility to vary the quantity of converting material used to derive the desired color. In use, the second converting material is used to absorb the light from LED chip for converting it to light in the non-visible range and in turns reduces the total visible light to the eye. As a result, the converted non-visible light does not influence the visible color and hence it is convenient to be used as a means to vary and control the total visible light output.

Furthermore, for practical applications, LED chips with higher light output (or higher optical power) are mixed with more quantity of the second converting material to reduce the total visible light output. Similarly, LED chips with lower light output (or lower optical power) are mixed with lower quantity or may even be employed without the second converting material. Consequently, with such control, the range of visible light output or the number of bins can be reduced as disclosed herein.

Therefore, as may be seen, various embodiments of the present invention disclose lighting systems and methods combining visible and non-visible light converting phosphor, which provide significant advantages, such as, for example, but not limited to, controlling the wavelength and the intensity of the LEDs and tuning the LEDs into specific bins, thereby reducing the number of bins.

Accordingly, while there has been shown and described the preferred embodiment of the invention is to be appreciated that the invention may be embodied otherwise than is herein specifically shown and described and, within the embodiment, certain changes may be made in the form and arrangement of the parts without departing from the underlying ideas or principles of this invention within the scope of the claims appended herewith.

1. A lighting system combining visible and non-visible light converting phosphor, said system comprising:
a light emitting diode (LED) package;
at least one light emitting diode (LED) chip mounted on said light emitting diode (LED) package;
a phosphor material covering said at least one light emitting diode (LED) chip, said phosphor material comprising a first converting material that emits in a visible light spectrum and a second converting material that emits in a non-visible light spectrum,
wherein the non-visible light spectrum is defined as a light having a peak wavelength of at least about 680 nm, and
wherein a spectral appearance of said lighting system is dependent upon a combination of said first converting material and said second converting material.

2. The system as claimed in claim 1, wherein said first converting material is phosphor having a peak wavelength of from about 430 to about 490 nm.

3. (canceled)

4. The system as claimed in claim 1, wherein said at least one light emitting diode (LED) is at least one of a blue chip and UV LED chip.

5. The system as claimed in claim 1, wherein said at least one light emitting diode (LED) chip belongs to at least one LED bin, said at least one LED bin having a corresponding light output performance with respect to at least one of a light wavelength and a light brightness.

6. The system as claimed in claim 1, wherein said combination of said first converting material and said second converting material provides at least one characteristic to said system.

7. The system as claimed in claim 6, wherein said at least one characteristic is dependent upon said first converting material that converts light in the visible light spectrum.

8. The system as claimed in claim 6, wherein said at least one characteristic is dependent upon said second phosphor converting material that converts light in the non-visible light spectrum.

9. A method of manufacturing a lighting system combining visible and non-visible light converting phosphor, said method comprising the steps of:
providing a light emitting diode (LED) package;
mounting at least one light emitting diode (LED) chip on said light emitting diode (LED) package;
covering said at least one light emitting diode (LED) chip with a phosphor material, said phosphor material comprising a first converting material that emits in a visible light spectrum and a second converting material that emits in a non-visible light spectrum,
wherein the non-visible light spectrum is defined as a light having a peak wavelength of at least about 680 nm, and
wherein a spectral appearance of said lighting system is dependent upon a combination of said first converting material and said second converting material.

10. The method as claimed in claim 9, wherein said first converting material is phosphor having a peak wavelength of from about 430 to about 490 nm.

11. (canceled)

12. The method as claimed in claim 9, wherein said at least one light emitting diode (LED) is at least one of a blue chip and UV LED chip.

13. The method as claimed in claim 9, wherein said method further comprises disposing said at least one light emitting diode (LED) chip belongs to at least one LED bin, said at least one LED bin having a corresponding light output performance with respect to at least one of a light wavelength and a light brightness.

14. The method as claimed in claim 9, wherein said at least one characteristic is dependent upon said combination of said first converting material and said second converting material.

15. The method as claimed in claim 9, wherein said combination of said first converting material and said second converting material provides at least one characteristic to said system.

16. The method as claimed in claim 15, wherein said at least one characteristic is dependent upon said first converting material that converts light in the visible light spectrum.

17. The method as claimed in claim 15, wherein said at least one characteristic is dependent upon said second converting material that converts light in the non-visible light spectrum.
